(19) United States
(12) Patent Application Publication
(10) Pub. No.: US 2007/0253576 A1
(43) Pub. Date: Nov. 1, 2007

(54) Method for virtual bass synthesis

(75) Inventors: Mingsian R. Bai, Hsinchu (TW); Wen-Liang Tseng, Toufen Township (TW); Wan-Chi Lin, Taipei City (TW)

Correspondence Address: BUCKNAM AND ARCHER, 1077 NORTHERN BOULEVARD, ROSLYN, NY, 11576, US

(73) Assignee: National Chiao Tung University, Hsinchu (TW)

(21) Appl. No.: 11/523,412

(22) Filed: Sep. 19, 2006

(30) Foreign Application Priority Data
Apr. 27, 2006 (TW) 095115005

(51) Int. Cl. H03G 5/00; H03G 3/00

(52) U.S. Cl. 381/98; 381/61

(57) ABSTRACT

This invention relates to a method for virtual bass synthesis. The low frequency signal is attained by applying a low pass filter to the original. In order to reduce the operations, process of down sampling the low frequency signal, moving the low frequency signal to a series of harmonics whose frequencies are integral times as large as the frequency of low frequency signals, and then up sampling them are provided. By means of psycho-acoustic theory, the weights of harmonics are attained and applied to the harmonics. Finally the weighted harmonics are combined to produce the bass signal. As the result, the virtual bass effect which is almost the same as the low frequency of the original audio signal can be accomplished. Because the harmonic signals are high frequency ones, the virtual effect can be made in the panel speakers or ordinary low-end speakers.

### TECHNICAL FIELD

The present invention relates to a method for audio synthesis, and particularly to a method for virtual bass synthesis.

### BACKGROUND OF THE INVENTION

Recently, to enjoy the audio/video entertainment becomes more and more important in human life. Those equipments, such as digital TV, MP3 player, handset, home theater, etc., not only should provide the ordinary sound effect functions, but also become more and more important to provide the additional special sound effect, and the performance of virtual bass is one of the important subject.

The ordinary speaker could not have good performance on the low frequency audio signal. In the past, in order to have the compact speaker or desktop multimedia speaker presenting virtual bass effect, it should increase the gain of low frequency signal, or add an additional virtual bass speaker to attain the virtual bass effect. However, the previous method will usually reduce the lifespan of the speaker due to the nonlinear distortion and physical damage. And, with the additional virtual bass speaker, it will have the defects of larger volume and higher cost, so it is not practical.

U.S. Pat. No. 5,930,373 describe a method for enhancing audio signal by adding multiple harmonics to simulate the low frequency. However, this method will give inappropriate weights to each harmonic signal, and cause the large distortion for the sound, and this method for enhancing audio signal needs a lot of operations, which causes the heavy loading to the processor.

### SUMMARY OF INVENTION

The object of the present invention is to provide a method for virtual bass synthesis, which could attain the virtual bass effect on an ordinary speaker, protect the lifespan of the speaker, reduce the cost, and reduce the operations without causing distortion.

The present invention provides a method for virtual bass synthesis, which includes the following steps:

first, passing an audio signal through a first low pass filter to abstract a bass signal from the audio signal;

next, using a method of the phase vocoder to execute a modulation on the bass signal to generate a plurality of harmonics;

then, referring to the equal-loudness contour to adjust the weight for each of the plurality of harmonics;

and, synthesizing these harmonics with the remaining portions of the audio signal after abstraction of bass signal according to the weight for each harmonic signal, so as to generate a virtual bass audio signal.

Moreover, the synthesis method in a preferred embodiment according to the present invention further includes the reduction of sampling frequency of the bass signal to simplify the modulation, and the increasing of sampling frequency of the harmonics to pass through a second low pass filter to remove the high frequency noise, and precisely synthesize the harmonics and the remaining portions of the audio signal after abstraction of bass signal to generate a virtual bass audio, wherein the frequency of the audio signal for the bass signal is within a range below 120 Hz.

Because the present invention uses multiple harmonics to generate the bass with different weights, and reduce the sampling frequency to reduce the operation structure, which could use the non-bass speaker, such as panel speaker or ordinary low-end speaker, to attain the virtual effect. Thus, the present invention could protect the lifespan of the speaker and reduce the cost, and also reduce the operation without distortion.

The objects, features, advantages and others of the present invention will become more apparent from the following detailed description in which reference is made to some embodiments of the invention and the appended drawings.

### BRIEF DESCRIPTION OF DRAWINGS

The invention will be more clearly understood after referring to the following detailed description read in conjunction with the drawings wherein:

FIG. 1 illustrates a frequency distribution diagram of the method for virtual bass synthesis in an embodiment according to the present invention;

FIG. 2 illustrates the equal-loudness contour;

FIG. 3 illustrates a down-frequency block diagram of the method for virtual bass synthesis in another embodiment according to the present invention;

FIG. 4 illustrates a frequency division diagram of the method for virtual bass synthesis in another embodiment according to the present invention;

FIG. 5 illustrates an up-frequency block diagram of the method for virtual bass synthesis in another embodiment according to the present invention; and,

FIG. 6 illustrates a flow diagram of the method for virtual bass synthesis in an embodiment according to the present invention.

### DETAILED DESCRIPTION OF PREFERRED EMBODIMENTS

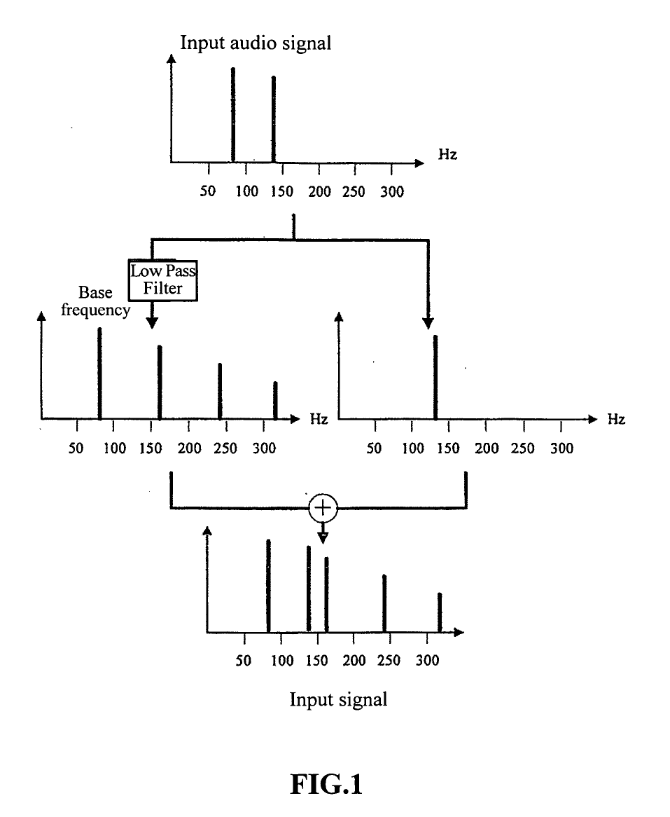

FIG. 1 illustrates a frequency distribution diagram of the method for virtual bass synthesis in an embodiment according to the present invention. When the input audio signal is a signal of 50 Hz and 130 Hz, the input audio signal will be passed through a low pass filter to attain a 50 Hz low frequency signal at the low pass frequency band. The high pass frequency band is for 130 Hz signal. The frequency of the audio signal for bass signal is within a range equal and below 120 Hz. The method uses the phase vocoder to attain a 50 Hz related harmonic sequence, and modulate the bass signal into harmonics with frequencies at 100 Hz, 150 Hz, 200 Hz, and 250 Hz. The phases of the harmonics should be the same as these of the original bass signal to achieve the effect without distortion. The embodiment is to generate the harmonics using 2˜5 frequency multiples for the bass signal. However, the present invention is not limited to use the 2˜5 frequency multiples. The person skilled in the art should understand to generate any integer frequency multiple of harmonics for the bass signal according to the design freedom.

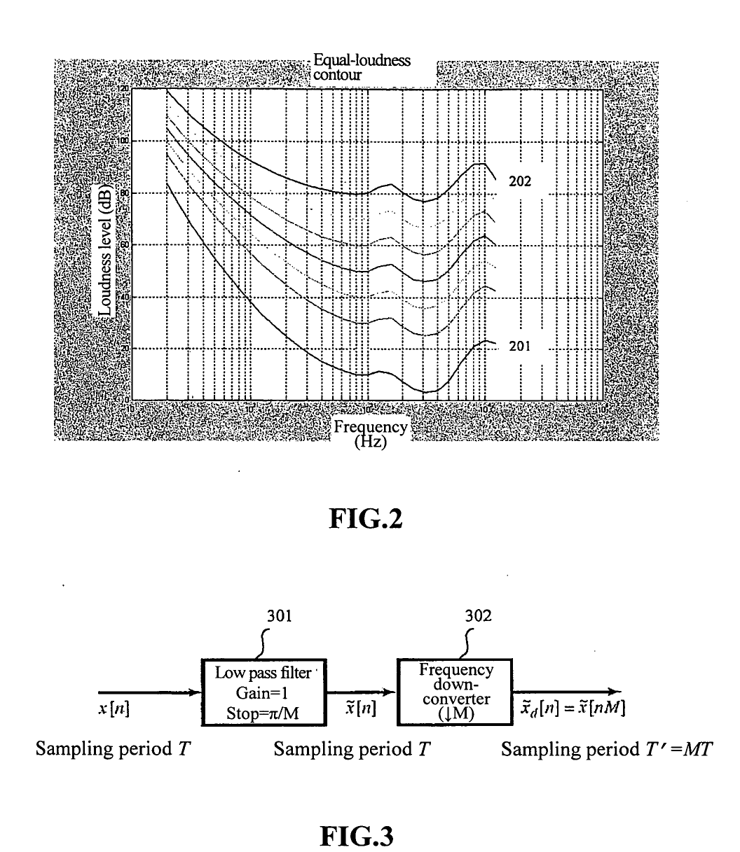

FIG. 2 illustrates the equal-loudness contour. Because the human ears will have different sensitivity to different frequencies of sound, the loudness contour represents the curves from a statistical method from experiments with equal loudness for different frequencies sensed by human ears. Referring to FIG. 2, it shows the human ears have less sensitivity to the lower frequency (smaller than 300 Hz) and the higher frequency (larger than 10 KHz). And, each curve is indicated with the sound level at 1 KHz. The unit for loudness level is called the phon, and the phon equals to the loudness level for each curve at 1 KHz (kilo Hertz). For example, on an equal-loudness curve 201, the audio signal for 40 Hz and 90 dB is 50 phon, and the curve with higher loudness is smoother. For the virtual bass in the embodiment, it uses the concept of equal-loudness level to determine the weight for each harmonic signal.

Making an example for the equal-loudness curve 201 with 20 phon in FIG. 2, the loudness level at 50 Hz is 55 dB, and the loudness level with the same loudness at 100 Hz is 38 dB, the loudness level at 150 Hz is 30 dB, and the loudness at 200 Hz is 24 dB, and so on. Thus, we could attain the volume of two times, three times, four times and five times of frequency multiples for 50 Hz relative to that volume at 50 Hz as the weight for each harmonic signal, and use the weight for each harmonic signal to generate the virtual bass to replace the bass. Finally, the method synthesizes each harmonic signal with the portions of the original audio signal higher than 120 Hz, so as to attain the audio signal equal to the original audio signal.

FIG. 3 illustrates a down sampling block diagram of the method for virtual bass synthesis in another embodiment according to the present invention. The embodiment is different from the previous embodiment for the reduction of operations. Normally, the sampling frequency for the audio signal is 44.1 kHz. Because the frequency of the bass signal is very low, it will have large repetitive operations on the bass signal data at the 44.1 kHz sampling frequency. The present embodiment reduces the original input audio signal to 1.6 kHz, so as to reduce the sampling frequency to reduce the data volume, and greatly reduce the operations.

In FIG. 3, if the sampling frequency of the original input audio signal x[n] is 44.1 KHz and the sampling period is T, before the reduction of sampling frequency, in order to abstract the bass signal, the original input audio signal should first be passed through the low pass filter 301, in which the gain for the low pass filter 301 is 1, and the stop period is π/M. Thus, the characteristic of the low pass filter 301 will not change the gain of the abstracted bass signal.

Furthermore, by considering the aliasing effect of the bass signal and the sampling frequency, the low pass filter 301 could remove the high frequency portions to exhibit the audio signal \tilde{x}[n] with the same sampling period at T. Meanwhile, because the frequency of the bass signal is below 120 Hz, it needs to use the frequency down-converter 302 to reduce the sampling frequency of 44.1 KHz to 1.6 kHz for preventing waste of too much operation. The audio signal through the frequency down-converter 302 is \tilde{x}d[n]=\tilde{x}[nM], in which the sampling period is T′=MT. If the sampling frequency is reduced from 44.1 KHz to 1.6 KHz, because the four times of frequency multiple for the base signal in 120 Hz is 480 Hz and a half of sampling frequency is the Nyquist frequency, the 480 Hz did not exceed the Nyquist frequency, and it will not exhibit the aliasing effect. Then, using the phase vocoder to execute a modulation on the base signal, it could generate the harmonics with the same phase, and with the integer times of frequencies for the bass signal.

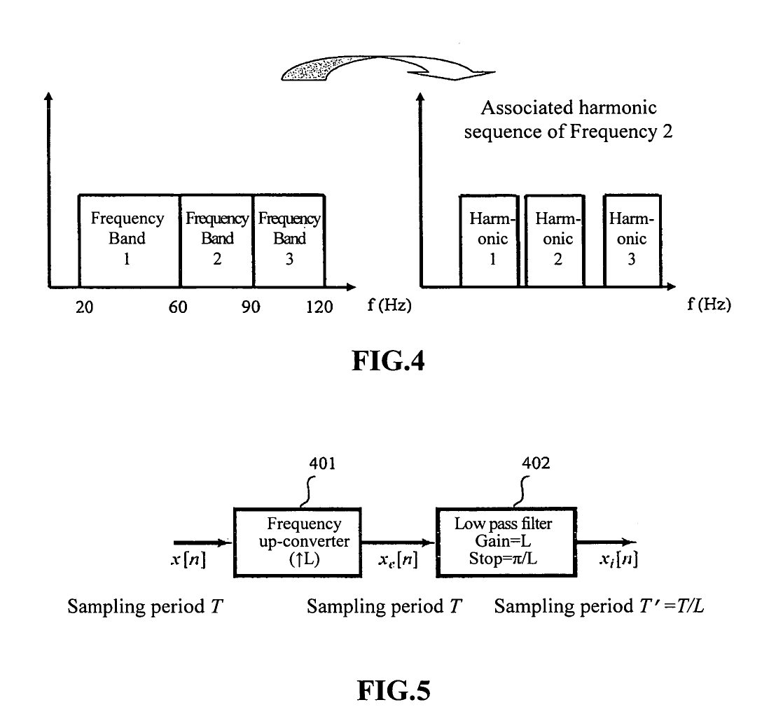

FIG. 4 illustrates a frequency division diagram for the method of virtual bass synthesis in another embodiment according to the present invention. When generating the low frequency signal having the frequency below 120 Hz, in order to more precisely attain a plurality of harmonics and the associated weights, we have divided the low frequency signal after frequency down-conversion into three frequency bands in the frequency domain: 20 Hz˜60 Hz, 60 Hz˜90 Hz, and 90 Hz˜120 Hz, and having the signals in the three frequency bands generating several high frequency harmonics, respectively. The reason for dividing frequency bands in a frequency domain is that, for a signal below 60 Hz, its two frequency multiples, or even three frequency multiples, are lower than the 120 Hz ultra-low frequency. Thus, for the speaker, they are the signals below the threshold frequency, so it must generate several harmonics with higher frequencies to replace the two frequency multiples and three frequency multiples of signals. Thus, the method for dividing into three frequency bands in the frequency domain and generating the corresponding high frequency harmonics on the three frequency bands to attain the corresponding weights could achieve more precisely bass effect.

FIG. 5 illustrates an up-frequency block diagram in the method for virtual bass synthesis in another embodiment according to the present invention. The bass signal after reducing sampling frequency will become the harmonics after modulation, in which the harmonics will keep the same sampling frequency at 1.6 kHz. At this time, it should use a frequency up-converter 401 to increase the harmonics to the original sampling frequency 44.1 kHz to be synthesized with the original audio signal after removal of bass signal. The sampling period for each harmonic signal x[n] is T. After passing the frequency up-converter 401, the sampling frequency will return to 44.1 kHz, and the sampling period for the harmonic signal xₑ[n] will become T′=T/L, wherein the signal in 44.1 kHz is suitable for playing on a PC (personal computer) or DSP (digital signal processor). The harmonic signal passing through the frequency up-converter 401 needs to be passed through the low pass filter 402, in which the gain of the low pass filter 402 is L, and the stop period is π/L. Because it will generate the high frequency portions after raising frequency, it will need the low pass filter 402 to filter out the high frequency portions to generate the up-frequency signal xᵢ[n], and keep the original sampling frequency; next, using the equal-loudness contour to attain the weight for each harmonic signal; finally, synthesizing these harmonics and the high frequency signal from the original audio signal passing the high pass filter based on the weight for each harmonic signal for output, so as to completely achieve the virtual bass.

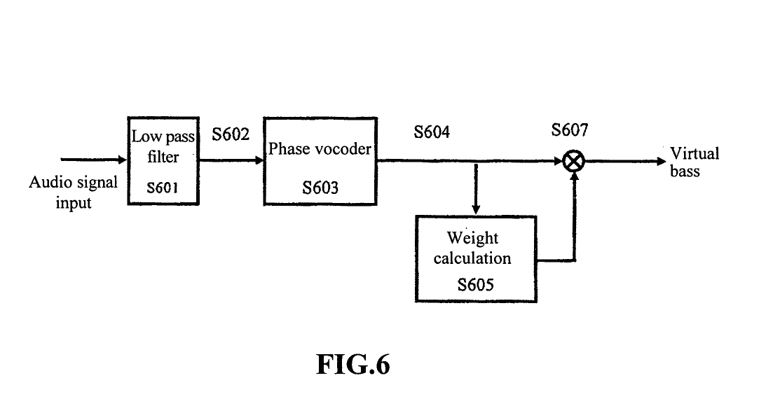

FIG. 6 illustrates a flow diagram of the method for virtual bass synthesis in an embodiment according to the present invention. The diagram of the method for virtual bass synthesis includes the following steps: first, in Step S601, passing an audio signal through a low pass filter to abstract a bass signal for the audio signal; next, in Step S603, using the phase vocoder to execute modulation on the bass signal to generate a plurality of harmonics; then, in Step S605, referring to the equal-loudness contour to adjust the weight for each of these harmonics; and, in Step S607, synthesizing the harmonics with the remaining portions of the audio signal after abstraction of bass signal to generate a virtual bass audio signal.

In a summary, in the method for virtual bass synthesis according to the present invention, because of using integer multiples of harmonics to generate the virtual bass, by reducing the sampling frequency to reduce the operations, and keeping the phase of each harmonic the same as that of the original audio signal to achieve a structure without distortion, it could effectively attain the bass effect on an ordinary speaker, such as panel speaker and ordinary low-end speaker. Thus, the method could protect the lifespan of the speaker and reduce the cost, and also reduce the operations without distortion.

Having illustrated and described the preferred embodiments according to the present invention, those skilled in the art should appreciate that these embodiments did not limit the present invention, and numerous changes and modifications may be made to these embodiments of the prevent invention, and that such changes and modifications may be made without departing from the scope and range of the present invention. Therefore, the scope and range of the present invention is defined by the appended claims.

### EXPLANATION OF MAIN COMPONENTS

201-203 Equal-loudness contour
301, 402, 502 Low Pass Filter
302 Frequency down-converter
401 Frequency up-converter
S601-S607 Steps of the method for virtual bass synthesis

We claim:

1. A method for virtual bass synthesis, which comprises the following steps:
passing an audio signal through a first low pass filter to abstract a bass signal from the audio signal;
using the phase vocoder to execute a modulation on the bass signal to generate a plurality of harmonics;
referring to the equal-loudness contour to adjust the weight for each of the plurality of harmonics; and,
synthesizing these harmonics with the remaining portions of the audio signal after abstraction of bass signal according to the weight for each harmonic signal, so as to generate a virtual bass audio signal.

2. The method for virtual bass synthesis as claimed in claim 1, wherein the phase for each of the harmonic signals is the same as the phase of the bass signal abstracted from the audio signal.

3. The method for virtual bass synthesis as claimed in claim 1, further comprises the step of reducing the sampling frequency of the bass signal to simplify the modulation, and increasing the sampling frequency for these harmonics to precisely synthesize these harmonics with the remaining portions of the audio signal after abstraction of the bass signal.

4. The method for virtual bass synthesis as claimed in claim 3, further comprises the step of passing these harmonics with increased sampling frequencies through a second low pass filter to remove the high frequency noise.

5. The method for virtual bass synthesis as claimed in claim 1, wherein the frequencies of these harmonics are the integer multiples of the frequency of the bass signal.

6. The method for virtual bass synthesis as claimed in claim 1, wherein the frequency for the audio signal of the bass signal is within the frequency range equal to and below 120 Hz.
